(19) United States
(12) Patent Application Publication
(10) Pub. No.: US 2024/0242771 A1
(43) Pub. Date: Jul. 18, 2024

(54) USING A SUBTHRESHOLD VOLTAGE FOR MAPPING IN MEMORY

(71) Applicant: Micron Technology, Inc., Boise, ID (US)

(72) Inventors: Agostino Pirovano, Milano (IT); Fabio Pellizzer, Boise, ID (US)

(21) Appl. No.: 18/407,129

(22) Filed: Jan. 8, 2024

Related U.S. Application Data
(60) Provisional application No. 63/438,659, filed on Jan. 12, 2023.

(51) Int. Cl. G11C 27/00

(52) U.S. Cl. CPC G11C 27/005

(57) ABSTRACT

Apparatuses, methods, and systems for using a subthreshold voltage for mapping in memory are disclosed. An example apparatus includes a memory array including a plurality of memory cells each programmable to a first data state or a second data state, and circuitry coupled to the memory array and configured to encode an input vector comprising a first number of data states to be programmed to a first group of memory cells of a memory array, apply a subthreshold voltage to each of a second group of memory cells of the memory array, wherein the second group of memory cells is programmed to a weight vector comprising a second number of data states and wherein the subthreshold voltage is based upon the data states of the input vector, and map the input vector to a location in the memory array using the weight vector after applying the subthreshold voltage.

### PRIORITY INFORMATION

This application claims the benefit of U.S. Provisional Application No. 63/438,659, filed on Jan. 12, 2023, the contents of which are incorporated herein by reference.

### TECHNICAL FIELD

The present disclosure relates generally to semiconductor memory and methods, and more particularly, to using a subthreshold voltage for mapping in memory.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), and resistance variable memory such as phase change random access memory (PCRAM), resistive random access memory (RRAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

Resistance variable memory devices can include resistance variable memory cells that can store data based on the resistance state of a storage element (e.g., a memory element having a variable resistance). As such, resistance variable memory cells can be programmed to store data corresponding to a target data state by varying the resistance level of the memory element. Resistance variable memory cells can be programmed to a target data state (e.g., corresponding to a particular resistance state) by applying sources of an electrical field or energy, such as positive or negative electrical pulses (e.g., positive or negative voltage or current pulses) to the cells (e.g., to the memory element of the cells) for a particular duration. A state of a resistance variable memory cell can be determined by sensing current through the cell responsive to an applied interrogation voltage. The sensed current, which varies based on the resistance level of the cell, can indicate the state of the cell.

Various memory arrays can be organized in various architectures, such as a vertical pillar architecture with memory cells (e.g., resistance variable cells) arranged in word line layers, or a cross-point architecture with memory cells (e.g., resistance variable cells) being located at intersections of a first and second signal lines used to access the cells (e.g., at intersections of word lines and bit lines). Some resistance variable memory cells can comprise a select element (e.g., a diode, transistor, or other switching device) in series with a storage element (e.g., a phase change material, metal oxide material, and/or some other material programmable to different resistance levels). Some resistance variable memory cells, which may be referred to as self-selecting memory cells, can comprise a single material which can serve as both a select element and a storage element for the memory cell.

### BRIEF DESCRIPTION OF THE DRAWINGS

FIG. 1 is a three-dimensional view of a portion of an example of a memory array, in accordance with an embodiment of the present disclosure.

FIG. 2A illustrates threshold voltage distributions associated with various states of memory cells, in accordance with an embodiment of the present disclosure.

FIG. 2B is an example of a current-versus-voltage curve corresponding to a memory state of FIG. 2A, in accordance with an embodiment of the present disclosure.

FIG. 2C is an example of a current-versus-voltage curve corresponding to another memory state of FIG. 2A, in accordance with an embodiment of the present disclosure.

FIG. 3 illustrates a group of memory cells programmed to a weight vector for mapping in memory, in accordance with an embodiment of the present disclosure.

FIG. 4 is a block diagram illustration of an example apparatus, in accordance with an embodiment of the present disclosure.

### DETAILED DESCRIPTION

The present disclosure includes apparatuses, methods, and systems for using a subthreshold voltage for mapping in memory. Apparatuses, methods, and systems for using a subthreshold voltage for mapping in memory are disclosed. An example apparatus includes a memory array including a plurality of memory cells each programmable to a first data state or a second data state, and circuitry coupled to the memory array and configured to encode an input vector comprising a first number of data states to be programmed to a first group of memory cells of a memory array, apply a subthreshold voltage to each of a second group of memory cells of the memory array, wherein the second group of memory cells is programmed to a weight vector comprising a second number of data states and wherein the subthreshold voltage is based upon the data states of the input vector, and map the input vector to a location in the memory array using the weight vector after applying the subthreshold voltage.

Mapping, as discussed herein, may utilize a map, (e.g., a self-organizing map) to map data to locations in a memory. A self-organizing map is a type of artificial Neural Network that can be trained. The training can utilize unsupervised learning to produce a low-dimensional, discretized representation of the input space of the training samples, which may be referred to as a map. The map may be utilized for dimensionality (e.g., distance) reduction, for example, in the memory.

Self-organizing maps can operate in two modes: a training mode and t a mapping mode. As mentioned, the training mode may be utilized to build the map using training samples (e.g., input examples). The training mode can be a competitive process and may be referred to as vector quantization. Once trained, the mapping mode can be utilized to classify and map a new input vector.

The map can include a map space that includes a number of nodes, which may also be referred to as neurons. The map space can be defined as a region (e.g., a finite two-dimensional region where the nodes are arranged in a hexagonal or rectangular grid). Each node can be associated with a respective weight vector. The weight vector can have a same dimension (e.g., “n”) as each input vector. Embodiments provide that n can have different values for various applications. For instance, n can have a value of 4, 6, 8, 10, or 12, among other values.

The training mode, which may be performed offline, can include moving weight vectors toward input data (e.g., reducing a distance metric) while maintaining the topology of the map space. Once trained, the mapping mode can be utilized (e.g., the map can be utilized to classify a vector from an input space by locating the node with the closest weight vector (smallest distance metric) to the input vector). Embodiments of the present disclosure are directed towards operations in the mapping mode.

Embodiments of the present disclosure provide low power consumption and/or high endurance for input vector processing and mapping in memory (e.g., resistance variable memory). To provide the low power consumption and/or the high endurance, embodiments of the present disclosure provide that a subthreshold voltage is utilized for input vector processing and mapping. Because the subthreshold voltage is utilized, the power consumption is low (e.g., as compared to utilizing threshold voltages for the mapping). Further, because the subthreshold voltage is utilized, the cells do not change data states during mapping, which results in a high endurance (e.g., as compared to utilizing cells that change data states for input vector processing and mapping).

As used herein, “a”, “an”, or “a number of” can refer to one or more of something, and “a plurality of” can refer to two or more such things. For example, a memory device can refer to one or more memory devices, and a plurality of memory devices can refer to two or more memory devices. Additionally, designators (e.g., “n”, “N”, and “M”) as used herein, particularly with respect to reference numerals in the drawings, indicates that a number of the particular feature so designated can be included with a number of embodiments of the present disclosure.

The figures herein follow a numbering convention in which the first digit or digits correspond to the drawing figure number and the remaining digits identify an element or component in the drawing. Similar elements or components between different figures may be identified by the use of similar digits.

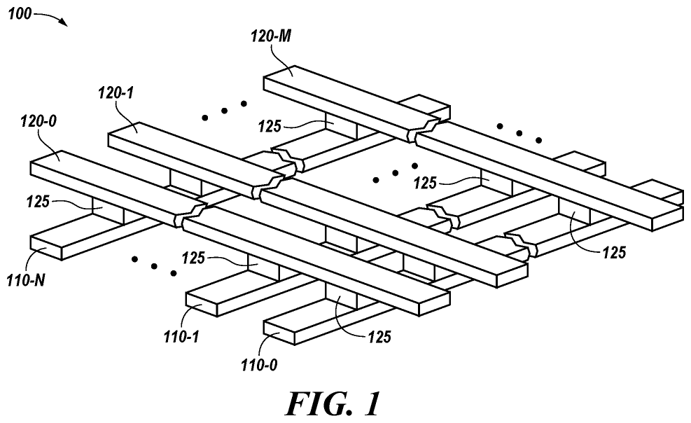

FIG. 1 is a three-dimensional view of an example of a memory array 100 (e.g., a cross-point memory array), in accordance with an embodiment of the present disclosure. Memory array 100 may include a plurality of first signal lines (e.g., first access lines), which may be referred to as word lines 110-0 to 110-N, and a plurality of second signal lines (e.g., second access lines), which may be referred to as bit lines 120-0 to 120-M) that cross each other (e.g., intersect in different planes). For example, each of word lines 110-0 to 110-N may cross bit lines 120-0 to 120-M. A memory cell 125 may be between the bit line and the word line (e.g., at each bit line/word line crossing).

The memory cells 125 may be resistance variable memory cells, for example. The memory cells 125 may include a material programmable to different data states, such as a set state, a reset state, and/or a “T” state. In some examples, each of memory cells 125 may include a single material, between a top electrode (e.g., top plate) and a bottom electrode (e.g., bottom plate), that may serve as a select element (e.g., a switching material) and a storage element, so that each memory cell 125 may act as both a selector device and a memory element. Such a memory cell may be referred to herein as a self-selecting memory cell. For example, each memory cell may include a chalcogenide material that may be formed of various doped or undoped materials, that may or may not be a phase-change material, and/or that may or may not undergo a phase change during reading and/or writing the memory cell. Chalcogenide materials may be materials or alloys that include at least one of the elements S, Se, and Te. Chalcogenide materials may include alloys of S, Se, Te, Ge, As, Al, Sb, Au, indium (In), gallium (Ga), tin (Sn), bismuth (Bi), palladium (Pd), cobalt (Co), oxygen (O), silver (Ag), nickel (Ni), platinum (Pt). Example chalcogenide materials and alloys may include, but are not limited to, Ge—Te, In—Se, Sb—Te, Ga—Sb, In—Sb, As—Te, Al—Te, Ge—Sb—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, or Ge—Te—Sn—Pt. Example chalcogenide materials can also include SAG-based glasses NON phase change materials such as SeAsGe. The hyphenated chemical composition notation, as used herein, indicates the elements included in a particular compound or alloy and is intended to represent all stoichiometries involving the indicated elements. For example, Ge—Te may include GexTey, where x and y may be any positive integer.

In various embodiments, the threshold voltages of memory cells 125 may snap back in response to a magnitude of an applied voltage differential across them exceeding their threshold voltages. Such memory cells may be referred to as snapback memory cells. For example, a memory cell 125 may change (e.g., snap back) from a non-conductive (e.g., high impedance) state to a conductive (e.g., lower impedance) state in response to the applied voltage differential exceeding the threshold voltage. For example, a memory cell snapping back may refer to the memory cell transitioning from a high impedance state to a lower impedance state responsive to a voltage differential applied across the memory cell being greater than the threshold voltage of the memory cell. A threshold voltage of a memory cell snapping back may be referred to as a snapback event, for example.

The architecture of memory array 100 may be referred to as a cross-point architecture in which a memory cell is formed at a topological cross-point between a word line and a bit line as illustrated in FIG. 1. Such a cross-point architecture may offer relatively high-density data storage with lower production costs compared to other memory architectures. For example, the cross-point architecture may have memory cells with a reduced area and, resultantly, an increased memory cell density compared to other architectures.

Embodiments of the present disclosure, however, are not limited to the example memory array architecture illustrated in FIG. 1. For example, embodiments of the present disclosure can include a three-dimensional memory array having a plurality of vertically oriented (e.g., vertical) access lines and a plurality of horizontally oriented (e.g., horizontal) access lines. The vertical access lines can be bit lines arranged in a pillar-like architecture, and the horizontal access lines can be word lines arranged in a plurality of conductive planes or decks separated (e.g., insulated) from each other by a dielectric material. The chalcogenide material of the respective memory cells of such a memory array can be located at the crossing of a respective vertical bit line and horizontal word line.

Further, in some architectures (not shown), a plurality of first access lines may be formed on parallel planes or tiers parallel to a substrate. The plurality of first access lines may be configured to include a plurality of holes to allow a plurality of second access lines formed orthogonally to the planes of first access lines, such that each of the plurality of second access lines penetrates through a vertically aligned set of holes (e.g., the second access lines vertically disposed with respect to the planes of the first access lines and the horizontal substrate). Memory cells including a storage element (e.g., self-selecting memory cells including a chalcogenide material) may be formed at the crossings of first access lines and second access lines (e.g., spaces between the first access lines and the second access lines in the vertically aligned set of holes). In a similar fashion as described above, the memory cells (e.g., self-selecting memory cells including a chalcogenide material) may be operated (e.g., read and/or programmed) by selecting respective access lines and applying voltage or current pulses.

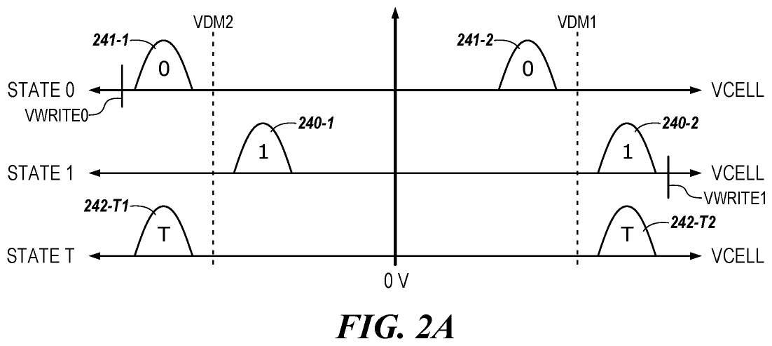

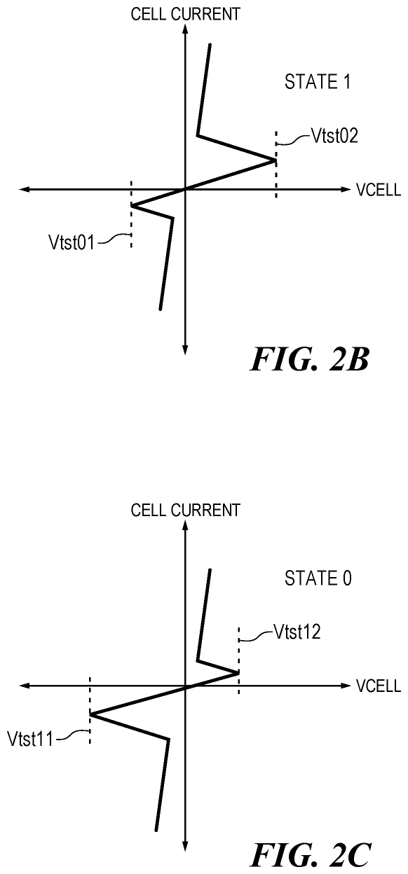

FIG. 2A illustrates threshold distributions associated with various states of memory cells, such as memory cells 125 illustrated in FIG. 1, in accordance with an embodiment of the present disclosure. For instance, as shown in FIG. 2A, the memory cells can be programmed to one of three possible data states (e.g., a first data state 0, a second state 1, or a third state T). That is, FIG. 2A illustrates threshold voltage distributions associated with three possible data states to which the memory cells can be programmed. Embodiments utilizing memory cells that can be programmed to one of three possible data states may be referred to as comprising a ternary self-organizing map. However, embodiments are not so limited. For instance, a number of embodiments may utilize memory cells that can be programmed to one of two possible data states (e.g., a first data state 0 or a second data state 1), such that the third state T is not available. Embodiments utilizing memory cells that can be programmed to one of two possible data states may be referred to as comprising a binary self-organizing map.

In FIG. 2A, the voltage VCELL may correspond to a voltage differential applied to (e.g., across) the memory cell, such as the difference between a bit line voltage (VBL) and a word line voltage (VWL) (e.g., VCELL=VBL−VWL). The threshold voltage distributions (e.g., ranges) 240-1, 240-2, 241-1, 241-2, 242-T1, and 242-T2 may represent a statistical variation in the threshold voltages of memory cells programmed to a particular state. The distributions illustrated in FIG. 2A correspond to the current versus voltage curves described further in conjunction with FIGS. 2B and 2C, which illustrate snapback asymmetry associated with assigned data states.

In some examples, the magnitudes of the threshold voltages of a memory cell 125 in a particular state may be asymmetric for different polarities, as shown in FIGS. 2A, 2B and 2C. For example, the threshold voltage of a memory cell 125 programmed to state 0 or state 1 may have a different magnitude in one polarity than in an opposite polarity. For instance, in the example illustrated in FIG. 2A, a first data state (e.g., state 0) is associated with a first asymmetric threshold voltage distribution (e.g., threshold voltage distributions 241-1 and 241-2) whose magnitude is greater for a negative polarity than a positive polarity, and a second data state (e.g., state 1) is associated with a second asymmetric threshold voltage distribution (e.g., threshold voltage distributions 240-1 and 240-2) whose magnitude is greater for a positive polarity than a negative polarity. In such an example, an applied voltage magnitude sufficient to cause a memory cell 125 to snap back can be different (e.g., higher or lower) for one applied voltage polarity than the other.

In some examples, the magnitudes of the threshold voltages of a memory cell 125 in a particular state may be symmetric for different polarities, as shown in FIG. 2A. For example, the threshold voltage of a memory cell 125 programmed to state T may have the same magnitude in opposite polarities. For instance, in the example illustrated in FIG. 2A, a third data state (e.g., state T) is associated with a symmetric threshold voltage distribution (e.g., threshold voltage distributions 242-T1 and 242-T2) whose magnitude is substantially equal (e.g. high) for both a positive polarity and a negative polarity. In such an example, an applied voltage magnitude sufficient to cause a memory cell 125 to snap back can be the same for different applied voltage polarities.

FIG. 2A illustrates demarcation voltages VDM1 and VDM2, which can be used to determine the state of a memory cell (e.g., to distinguish between states as part of a read operation). In this example, VDM1 is a positive voltage used to distinguish cells in state 0) (e.g., in threshold voltage distribution 241-2) from cells in state 1 (e.g., threshold voltage distribution 240-2) or state T (e.g., threshold voltage distribution 242-T2). Similarly, VDM2 is a negative voltage used to distinguish cells in state 1 (e.g., threshold voltage distribution 240-1) from cells in state 0) (e.g., threshold voltage distribution 241-1) or state T (e.g., threshold voltage distribution 242-T1). In the examples of FIGS. 2A-2C, a memory cell 125 in a positive state 1 or T does not snap back in response to applying VDM1: a memory cell 125 in a positive state 0 snaps back in response to applying VDM1: a memory cell 125 in a negative state 1 snaps back in response to applying VDM2: and a memory cell 125 in a negative state 0 or T does not snap back in response to applying VDM2.

Embodiments are not limited to the example shown in FIG. 2A. For example, the designations of state 0 and state 1 can be interchanged (e.g., distributions 241-1 and 241-2 can be designated as state 1 and distributions 240-1 and 240-2 can be designated as state 0).

FIGS. 2B and 2C are examples of current-versus-voltage curves corresponding to the memory states of FIG. 2A, in accordance with an embodiment of the present disclosure. As such, in this example, the curves in FIGS. 2B and 2C correspond to cells in which state 1 is designated as the higher threshold voltage state in a particular polarity (positive polarity direction in this example), and in which state 0 is designated as the higher threshold voltage state in the opposite polarity (negative polarity direction in this example). As noted above, the state designation can be interchanged such that state 0 could correspond to the higher threshold voltage state in the positive polarity direction with state 1 corresponding to the higher threshold voltage state in the negative direction.

FIGS. 2B and 2C illustrate memory cell snapback as described herein. VCELL can represent an applied voltage across the memory cell. For example, VCELL can be a voltage applied to a top electrode corresponding to the cell minus a voltage applied to a bottom electrode corresponding to the cell (e.g., via a respective word line and bit line). As shown in FIG. 2B, responsive to an applied positive polarity voltage (VCELL), a memory cell programmed to state 1 (e.g., threshold voltage distribution 240-2) is in a non-conductive state until VCELL reaches voltage Vtst02, at which point the cell transitions to a conductive (e.g., lower resistance) state. This transition can be referred to as a snapback event, which occurs when the voltage applied across the cell (in a particular polarity) exceeds the cell's threshold voltage. Accordingly, voltage Vtst02 can be referred to as a snapback voltage. In FIG. 2B, voltage Vtst01 corresponds to a snapback voltage for a cell programmed to state 1 (e.g., threshold voltage distribution 240-1). That is, as shown in FIG. 2B, the memory cell transitions (e.g., switches) to a conductive state when VCELL exceeds Vtst01 in the negative polarity direction.

Similarly, as shown in FIG. 2C, responsive to an applied negative polarity voltage (VCELL), a memory cell programmed to state 0) (e.g., threshold voltage distribution 241-1) is in a non-conductive state until VCELL reaches voltage Vtst11, at which point the cell snaps back to a conductive (e.g., lower resistance) state. In FIG. 2C, voltage Vtst12 corresponds to the snapback voltage for a cell programmed to state 0 (e.g., threshold voltage distribution 241-2). That is, as shown in FIG. 2C, the memory cell snaps back from a high impedance non-conductive state to a lower impedance conductive state when VCELL exceeds Vtst12 in the positive polarity direction.

In various instances, a snapback event can result in a memory cell switching states. For instance, if a VCELL exceeding Vtst02 is applied to a state 1 cell, the resulting snapback event may reduce the threshold voltage of the cell to a level below VDM1, which would result in the cell being read as state 0 (e.g., threshold voltage distribution 241-2). As such, in a number of embodiments, a snapback event can be used to write a cell to the opposite state (e.g., from state 1 to state (and vice versa).

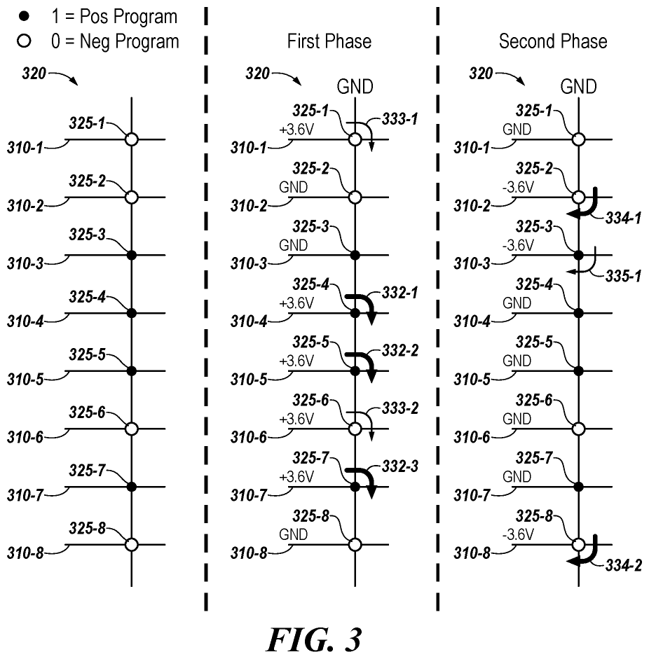

FIG. 3 illustrates a group (e.g., column) of memory cells 325-1, 325-2, . . . , 325-8 (which may be collectively referred to as memory cells 325) programmed to a weight vector for mapping in memory, in accordance with an embodiment of the present disclosure. The memory cells 325 can be part of a memory array (e.g., a resistance variable memory array, as discussed herein). For instance, the memory cells 325 can comprise a single column 320 of the memory array.

The weight vector can be described has having n vector components. For the example illustrated in FIG. 3, the weight vector includes (e.g., can be encoded with) eight vector components (n is 8), i.e., (00111010). While eight vector components are shown, embodiments are not so limited: a weight vector may have fewer than or greater than eight vector components (e.g., “n” may have various values for different applications). For instance, n can be 4, 6, 8, 10, or 12, among other values. The vector components can correspond to a data state (e.g., a value) to which respective memory cells are programmed.

As mentioned, the weight vector shown in FIG. 3 includes eight vector components (e.g., 00111010), where a first vector component position corresponds to a memory cell (325-1) programmed to a first data state (0), a second vector component position corresponds to a memory cell (325-2) programmed to the first data state (0), a third vector component position corresponds to a memory cell (325-3) programmed to a second data state (1), a fourth vector component position corresponds to a memory cell (325-4) programmed to the second data state (1), a fifth vector component position corresponds to a memory cell (325-5) programmed to the second data state (1), a sixth vector component position corresponds to a memory cell (325-6) programmed to the first data state (0), a seventh vector component position corresponds to a memory cell (325-7) programmed to the second data state (1), and an eighth vector component position corresponds to a memory cell (325-8) programmed to the first data state (0).

The weight vector (00111010) can be stored in a column 320 (e.g., one of second access lines 120 discussed in FIG. 1) by utilizing positive polarity programming for storing the “1”s of the weight vector and utilizing negative polarity programming for storing the “0”s of the weight vector. As an example, a half-selection voltage scheme can be applied to the rows 310-1, 310-2, 310-3, 310-4, 310-5, 310-6, 310-7, 310-8 (e.g., first access lines discussed in FIG. 1) and column 320.

The weight vector can be utilized to map an input vector to a location in the memory array (e.g., based on a distance between the input vector and the weight vector). For example, an input vector can be encoded to another group of memory cells of the array (e.g., an input vector comprising a first number of data states to be programmed to a first group of memory cells of the memory array). Embodiments provide that the input vector and the weight vector have a same number of vector components (e.g., both vectors have n vector components). For this discussion, the input vector can have (e.g., can be encoded) eight vector components (e.g., 10011110) where the first vector component position corresponds to a memory cell programmed to the second data state (1), the second vector component position corresponds to a memory cell programmed to the first data state (0), the third vector component position corresponds to a memory cell programmed to the first data state (0), the fourth vector component position corresponds to a memory cell programmed to the second data state (1), the fifth vector component position corresponds to a memory cell programmed to the second data state (1), the sixth vector component position corresponds to a memory cell programmed to the second data state (1), the seventh vector component position corresponds to a memory cell programmed to the second data state (1), and the eighth vector component position corresponds to a memory cell programmed to the first data state (0).

One or embodiments provide that a subthreshold voltage can be applied to each of a group of memory cells, wherein the group of memory cells is programmed to a weight vector comprising a number of data states and wherein the subthreshold voltage is based upon the data states of the input vector. That is, the subthreshold voltage can be applied to the group of memory cells 325. As used herein, a “subthreshold voltage” can refer to voltage of a magnitude that is less than the magnitude of the memory cell(s) to which it is being applied.

The subthreshold voltage can be applied in a positive polarity and a negative polarity. As shown in FIG. 3, a positive polarity subthreshold voltage of +3.6V and a negative polarity subthreshold voltage of −3.6V may be utilized: however, embodiments are not so limited and other positive polarity subthreshold voltages and/or negative polarity subthreshold voltages may be utilized. Embodiments provide that an absolute value of the positive polarity voltage is less than an absolute value of a positive threshold voltage value of the memory cells and that an absolute value of the negative polarity voltage is less than an absolute value of a negative threshold voltage value of the memory cells. A ground voltage can be applied a number of memory cells corresponding to the weight vector, when the subthreshold voltage is being applied to other memory cells corresponding to the weight vector. For instance, the bias of each memory cell corresponding to the weight vector can be set to ground.

As an example in a first phase, as indicated in FIG. 3, a positive polarity subthreshold voltage can be applied to a number of memory cells corresponding to the weight vector. One or more embodiments provide that the positive polarity subthreshold voltage can be applied to memory cells corresponding to vector components of the weight vector, where memory cells corresponding to vector components of the input vector are programmed to a particular data state (e.g., the data state (1)). For instance, as mentioned for this example, the input vector can have eight vector components (10011110), where the first, fourth, fifth, sixth, and seventh vector components each respectively corresponds to a memory cell programmed to the particular data state (1). Embodiments provide that the positive polarity subthreshold voltage can be applied to memory cells corresponding to the first, fourth, fifth, sixth, and seventh vector components of the weight vector (e.g., memory cells 325-1, 325-4 325-5, 325-6, and 325-7), while the ground voltage can be applied to memory cells corresponding to the second, third, and eight vector components of the weight vector (e.g., memory cells 325-2, 325-3, and 325-8).

When the positive polarity subthreshold voltage is applied, subthreshold leakage flows from the rows 310 to the column 320 predominantly from positively programmed memory cells (e.g., those memory cells 325-4 325-5, 325-7 of the weight vector programmed to data state (1)). In FIG. 3, for the first phase, relatively larger subthreshold leakage flows are indicated by relatively larger positive polarity subthreshold leakage flow indicators 332-1, 332-2, 332, as compared to relatively smaller positive polarity subthreshold leakage flow indicators 333-1, 333-2, or no positive polarity subthreshold leakage flow indicator (e.g., corresponding to memory cells 310-2, 310-3, 310-8).

The current into the column 320 for the first phase, which contributes to the column leakage, corresponds to three memory cells 325-4 325-5, 325-7 of the weight vector programmed to data state (1) and two memory cells 320-1, 320-6 of the weight vector programmed to data state (0). A subthreshold leakage flow from the application of the positive polarity subthreshold voltage can be determined and be utilized for mapping the input vector to a location in the memory array.

Thereafter, in a second phase, as indicated in FIG. 3, a negative polarity subthreshold voltage can be applied to a number of memory cells corresponding to the weight vector. One or more embodiments provide that the negative polarity subthreshold voltage can be applied to memory cells corresponding to vector components of the weight vector, where memory cells corresponding to vector components of the input vector are programmed to a particular data state (e.g. the data state (0)). For instance, as mentioned for this example, the input vector can have eight vector components (10011110), where the second, third, and eighth vector components each respectively corresponds to a memory cell programmed to the particular data state (0). Embodiments provide that the negative polarity subthreshold voltage can be applied to memory cells corresponding to the second, third, and eighth vector components of the weight vector (e.g., memory cells 325-2, 325-3, and 325-8), while the ground voltage can be applied to memory cells corresponding to the first, fourth, fifth, sixth, and seventh vector components of the weight vector (e.g., memory cells 325-1, 325-4 325-5, 325-6, and 325-7).

Subthreshold leakage flows from the rows 310 to the column 320 predominantly from negatively programmed memory cells (e.g., those memory cells 325-2, 325-8 of the weight vector programmed to data state (0)). In FIG. 3, for the second phase, relatively larger subthreshold leakage flows are indicated by relatively larger negative polarity subthreshold leakage flow indicators 334-1, 334-2, as compared to relatively smaller negative polarity subthreshold leakage flow indicator 335-1, or no positive polarity subthreshold leakage flow indicator (e.g., corresponding to memory cells 310-1, 310-4, 310-5, 310-6, 310-7).

The current into the column 320 for the second phase, which contributes to the column leakage, corresponds to two memory cells 325-2, 325-8 of the weight vector programmed to data state (0) and one memory cell 320-3 of the weight vector programmed to data state (1). A subthreshold leakage flow from the application of the negative polarity subthreshold voltage can be determined and be utilized for mapping the input vector to a location in the memory array.

As mentioned, the subthreshold leakage flow from the application of the positive polarity subthreshold voltage and the subthreshold leakage flow from the application of the negative polarity subthreshold voltage can be utilized for mapping the input vector to a location in the memory array. One or more embodiments provide that a total subthreshold leakage flow can be determined as a combination of the subthreshold leakage flow from the application of the positive polarity subthreshold voltage and the subthreshold leakage flow from the application of the negative polarity subthreshold voltage. As such, a total voltage difference between the values stored in the first phase and the second phase can be determined (e.g., by determining a total current flow resultant from applying the positive polarity subthreshold voltage and a total current flow resultant from applying the negative polarity subthreshold voltage).

The total current flow resultant from applying the positive polarity subthreshold voltage and the total current flow resultant from applying the negative polarity subthreshold voltage can be compared to one another (e.g., a difference can be determined, such that the input vector can be mapped to a location in the memory based on a result of the comparison). This method can be repeated for a plurality of weight vectors, wherein a particular weight vector corresponding to a greatest voltage difference, as compared to other weight vectors, can be determined as having a smallest distance metric. This method can be repeated for a plurality of input vectors. Having the smallest distance metric, the particular weight vector can be considered to be the winner, as compared to the other weight vectors. Having the smallest distance metric (e.g., being considered the winning weight vector) can be considered as having a minimum Hamming distance. Different distances (e.g., corresponding to different weight vectors) can be determined to be greater than, less than, or equal to one another. One or more embodiments provide that a number of various procedures may be utilized to determine a winning weight vector when equal distances occur. One or more embodiments provide that determining the Hamming distance can include an XNOR operation followed by bit-counting. One or more embodiments provide that the determined Hamming distance(s) (e.g., the determined winning weight vector) can be utilized as a training parameter (e.g., for the training mode previously mentioned).

As an example, an input vector (10011110), a first weight vector (00111010), and a second weight vector (10011010) can be utilized. In the first phase, a positive polarity subthreshold voltage can be applied to memory cells corresponding to vector components of the weight vectors, where memory cells corresponding to vector components of the input vector are programmed to a particular data state (e.g. the data state (1)), which may be considered to be a SET state, where the data state (0) may be considered a RESET state. In this example, for the first phase, the positive polarity subthreshold voltage can be applied to memory cells corresponding to the first, fourth, fifth, sixth, and seventh vector components of the respective weight vectors.

For the first phase, the first weight vector (00111010) will provide 3 SET state leak values (corresponding to the 4th, 5th, and 7th vector components) and 2 RESET leak values (corresponding to the 1st and 6th vector components): the second weight vector (10011010) will provide 4 SET state leak values (corresponding to the 1st, 4th, 5th, and 7th vector components) and 1 RESET leak value (corresponding to the 6th vector component). With the positive polarity subthreshold voltage, subthreshold leakage flows predominantly from positive programmed memory cells (e.g., those memory cells of the weight vectors programmed to data state (1)). As such, the total current flow resultant from applying the positive polarity subthreshold voltage is greater for the second weight vector, as compared to the first weight vector.

In the second phase, a negative polarity subthreshold voltage can be applied to memory cells corresponding to vector components of the weight vectors, where memory cells corresponding to vector components of the input vector are programmed to a particular data state (e.g. the data state (0))). In this example, for the second phase, the negative polarity subthreshold voltage can be applied to memory cells corresponding to the second, third, and eighth vector components of the respective weight vectors.

For the second phase, the first weight vector (00111010) will provide 2 RESET state leak values (corresponding to the 2nd and 8th vector components) and 1 SET leak value (corresponding to the 3rd vector component); the second weight vector (10011010) will provide 3 RESET state leak values (corresponding to the 2nd, 3rd, and 8th vector components) and 0 SET leak values. With the negative polarity subthreshold voltage, subthreshold leakage flows predominantly from negative programmed memory cells (e.g., those memory cells of the weight vectors programmed to data state (0))). As such, the absolute value of total current flow resultant from applying the negative polarity subthreshold voltage is greater for the second weight vector, as compared to the first weight vector.

A difference (e.g., Hamming distance) can be determined between the input vector and each of the first and second weight vectors. For instance, total current flow (by application of both the positive polarity subthreshold voltage and the negative polarity subthreshold voltage) from memory cells corresponding to the first weight vector and memory cells corresponding to the second weight vector can be compared (e.g., to determine which weight vector provides a relatively greater current flow). For this example, the total current flow provided by the second weight vector (10011010) (by application of both the positive polarity subthreshold voltage and the negative polarity subthreshold voltage) is greater than the total current flow provided by the first weight vector (00111010) (by application of both the positive polarity subthreshold voltage and the negative polarity subthreshold voltage). As such, the second weight vector can be determined as having shortest distance (e.g., the smallest distance metric), as compared to the first weight vector, and the second weight vector can be considered to be the winner. As mentioned, having the smallest distance metric (e.g., being considered the winning weight vector) can be considered as having a minimum Hamming distance.

As mentioned, a number of embodiments provide that memory cells that can be programmed to one of two possible data states (e.g., a first data state 0 or a second data state 1) may be utilized, which can be referred to as a binary self-organizing map: and a number of embodiments provide that memory cells that can be programmed to one of three possible data states (e.g., a first data state 0, a second state 1, or a third state T) may be utilized, which can be referred to as a ternary self-organizing map. Further, as discussed herein, input vectors can be translated into biases (e.g., row biases) having different polarities. For instance: the positive polarity subthreshold voltage can be applied corresponding to instances of the data state 0) for the input vector for both the binary self-organizing map and the ternary self-organizing map: the negative polarity subthreshold voltage can be applied corresponding to instances of the data state 1 for the input vector for both the binary self-organizing map and the ternary self-organizing map: and a ground voltage can be applied corresponding to instances of the data state T for the input vector for the ternary self-organizing map. As discussed herein, the biases are maintained in the subthreshold region of the memory cells, which provides a relatively high current leakage when the input bias polarity matches the programmed polarity of vector components of a weigh vector and a relatively low current leakage when the input bias polarity does not match the programmed polarity of vector components of the weigh vector.

As mentioned, the memory cells are not subject to a threshold voltage (e.g., a subthreshold voltage is utilized) during mapping operations as discussed herein. This provides a low power consumption during mapping operations and provides that the memory cells endurance is not diminished by switching data states during mapping operations.

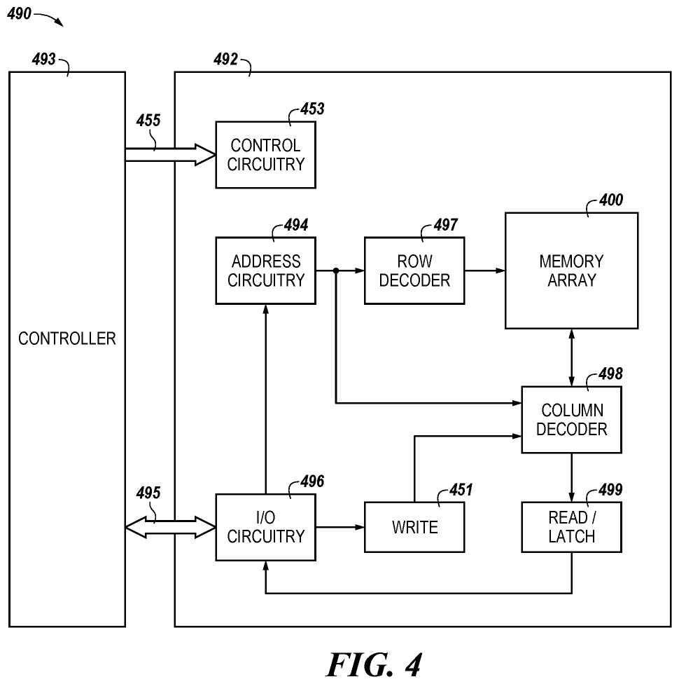

FIG. 4 is a block diagram illustration of an example apparatus, such as an electronic memory system 490, in accordance with an embodiment of the present disclosure. Memory system 490 may include an apparatus, such as a memory device 492 and a controller 493, such as a memory controller (e.g., a host controller). Controller 493 might include a processor, for example. Controller 493 might be coupled to a host, for example, and may receive command signals (or commands), address signals (or addresses), and data signals (or data) from the host and may output data to the host. One or more embodiments provide that controller 493 can perform one or more operations for using a subthreshold voltage for mapping in memory (e.g., in memory array 400), in accordance with the present disclosure.

Memory device 492 includes a memory array 400 of memory cells. For example, memory array 400 may include one or more of the memory arrays, such as a cross-point memory array, of memory cells discussed herein. Although one memory array 400 is illustrated in FIG. 4 for simplicity and so as not to obscure embodiments of the present disclosure, memory device 492 can include a number of memory arrays analogous to array 400.

Memory device 492 may include address circuitry 494 to latch address signals provided over I/O connections 495 through I/O circuitry 496. Address signals may be received and decoded by a row decoder 497 and a column decoder 498 to access the memory array 400.

Memory device 492 may sense (e.g., read) data in memory array 400 by sensing voltage and/or current changes in the memory array columns using sense/buffer circuitry that in some examples may be read/latch circuitry 499. Read/latch circuitry 499 may read and latch data from the memory array 400. Sensing circuitry (not shown) may include a number of sense amplifiers coupled to memory cells of memory array 400, which may operate in combination with the read/latch circuitry 499 to sense (e.g., read) memory states from targeted memory cells. I/O circuitry 496 may be included for bi-directional data communication over the I/O connections 495 with controller 493. Write circuitry 451 may be included to write data to memory array 400.

Control circuitry 453 may decode signals provided by control connections 455 from controller 493. These signals may include chip signals, write enable signals, and address latch signals that are used to control the operations on memory array 400, including data read and data write operations.

Control circuitry 453 may be included in controller 493, for example. Controller 493 may include other circuitry, firmware, software, or the like, whether alone or in combination. Controller 493 may be an external controller (e.g., in a separate die from the memory array 400, whether wholly or in part) or an internal controller (e.g., included in a same die as the memory array 400). For example, an internal controller might be a state machine or a memory sequencer.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a memory array including a plurality of memory cells, wherein each of the plurality of memory cells is programmable to a first data state or a second data state; and
circuitry coupled to the memory array, wherein the circuitry is configured to:
encode an input vector comprising a first number of data states to be programmed to a first group of memory cells of the memory array;
apply a subthreshold voltage to each of a second group of memory cells of the memory array, wherein the second group of memory cells is programmed to a weight vector comprising a second number of data states and wherein the subthreshold voltage is based upon the data states of the input vector; and
map the input vector to a location in the memory array using the weight vector after applying the subthreshold voltage.

2. The apparatus of claim 1, wherein the circuitry is configured to apply the subthreshold voltage in a positive polarity and a negative polarity.

3. The apparatus of claim 2, wherein the positive polarity subthreshold voltage is applied to the memory cells of the second group that are programmed to the first data state.

4. The apparatus of claim 3, wherein the circuitry is configured to apply a ground voltage to the memory cells of the second group that are programmed to the second data state while the positive polarity subthreshold voltage is applied to the memory cells of the second group that are programmed to the first data state.

5. The apparatus of claim 2, wherein the negative polarity subthreshold voltage is applied to the memory cells of the second group that are programmed to the second data state.

6. The apparatus of claim 5, wherein the circuitry is configured to apply a ground voltage to the memory cells of the second group that are programmed to the first data state while the negative polarity subthreshold voltage is applied to the memory cells of the second group that are programmed to the second data state.

7. The apparatus of claim 2, wherein the circuitry is configured to determine a total current flow resultant from applying the positive polarity subthreshold voltage and a total current flow resultant from applying the negative polarity subthreshold voltage.

8. The apparatus of claim 7, wherein the circuitry is configured to:
compare the total current flow resultant from applying the positive polarity subthreshold voltage to the total current flow resultant from applying the negative polarity subthreshold voltage; and
map the input vector to the location in the memory based on a result of the comparison.

9. The apparatus of claim 1, wherein each of the plurality of memory cells is programmable to a third data state.

10. The apparatus of claim 9, wherein the circuitry is configured to:
apply the subthreshold voltage in a positive polarity to the memory cells of the second group that are programmed to the first data state;
apply the subthreshold voltage in a negative polarity to the memory cells of the group that are programmed to the second data state; and
apply the subthreshold voltage at ground to the memory cells of the group that are programmed to the third data state.

11. A method of operating memory, comprising:
providing an input vector to a memory array including a plurality of memory cells, wherein the input vector is encoded with a first plurality of values corresponding to a first plurality of data states to be programmed to a first group of memory cells of the memory array;
applying a positive polarity voltage to memory cells of a second group of memory cells of the memory array that are programmed to the first data state;
applying a negative polarity voltage to memory cells of the second group that are programmed to the second data state, wherein the second group of memory cells is programmed to a weight vector comprising a second plurality of values corresponding to a second plurality of data states; and
mapping the input vector to a location in the memory array using the weight vector based on a result of applying the positive polarity voltage and the negative polarity voltage.

12. The method of claim 11, wherein the second group of memory cells comprises a single column of the memory array.

13. The method of claim 11, wherein an absolute value of the positive polarity voltage is less than an absolute value of a positive threshold voltage value of the memory cells of the second group of memory cells.

14. The method of claim 11, wherein an absolute value of the negative polarity voltage is less than an absolute value of a negative threshold voltage value of the memory cells of the second group of memory cells.

15. The method of claim 11, wherein the method includes:
determining a distance between the input vector and the weight vector by summing a total voltage value difference between the first plurality of values corresponding to the first plurality of data states to be programmed to the first group of memory cells of the memory array and the second plurality of values corresponding to the second plurality of data states; and
mapping the input vector to the location in the memory array based on the determined distance.

16. The method of claim 15, wherein the method includes:
comparing the distance between the input vector and the weight vector to an additional difference between the input vector and an additional weight vector to determine a shortest difference; and
mapping the input vector to the location in the memory array based on the determined shortest distance.

17. An apparatus, comprising:
a memory array including a plurality of memory cells, wherein each of the plurality of memory cells is programmable to a first data state, a second data state, or a third data state; and
circuitry coupled to the array of memory cells, wherein the circuitry is configured to:
encode an additional weight vector with a third plurality of values each corresponding to one of the first data state, the second data state, and the third data state;
apply a positive polarity subthreshold voltage to memory cells of the array corresponding to vector component positions of the additional weight vector for each value of the input vector corresponding to the first data state;
apply a negative polarity subthreshold voltage to memory cells of the array corresponding to vector component positions of the additional weight vector for each value of the input vector corresponding to the second data value;
apply a ground voltage to memory cells of the array corresponding to vector component positions of the additional weight vector for each value of the input vector corresponding to the third data value; and
map the input vector to an additional location in the memory array using the additional weight vector after applying the positive polarity subthreshold voltage, the negative polarity subthreshold voltage, and the ground subthreshold voltage.

18. The apparatus of claim 17, wherein the circuitry is configured to:
encode an additional weight vector with a third plurality of values corresponding to one or more of the first data state, the second data state, and the third data state, wherein the another weight vector has n dimensions;
apply a positive polarity subthreshold voltage to memory cells corresponding to vector component positions of the another weight vector for each vector component of the input vector corresponding to the first data value;
apply a negative polarity subthreshold voltage to memory cells corresponding to vector component positions of the another weight vector for each vector component of the input vector corresponding to the second data value; and
apply a ground voltage to memory cells corresponding to vector component positions of the another weight vector for each vector component of the input vector corresponding to the third data value.

19. The apparatus of claim 18, wherein the circuitry is configured to:
determine a first distance between the input vector and the weight vector and a second distance between the input vector and the additional weight vector based on the application of the positive polarity subthreshold voltage, the negative polarity subthreshold voltage, and the ground voltage; and
map the input vector to the location in the memory array based on the determined distance.

20. The apparatus of claim 19, wherein the circuitry is configured to:
determine whether the first distance is greater than, less than, or equal to the second distance; and
map the input vector to the location in the memory based on whether the first distance is greater than, less than, or equal to the second distance.
